(19) United States
(12) Patent Application Publication
(10) Pub. No.: US 2010/0019767 A1
(43) Pub. Date: Jan. 28, 2010

(54) RF COIL ASSEMBLY FOR A MAGNETIC RESONANCE IMAGING SYSTEM

(75) Inventors: Zang Hee CHO, Incheon (KR); Young Bo KIM, Gyeonggi-do (KR); Jae Yong HAN, Seoul (KR); Kyoung Nam KIM, Incheon (KR); Jung Hwan KIM, Seoul (KR); Suk Min HONG, Incheon (KR)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: GACHON UNIVERSITY OF MEDICINE & SCIENCE INDUSTRY- ACADEMIC COOPERATION FOUNDATION, Incheon (KR)

(21) Appl. No.: 12/372,339

(22) Filed: Feb. 17, 2009

(30) Foreign Application Priority Data
Jul. 24, 2008 (KR) 10-2008-0072186

(51) Int. Cl. G01R 33/32

(52) U.S. Cl. 324/318

(57) ABSTRACT

An RF (radio frequency) coil assembly of a magnetic resonance imaging (MRI) system, which has a spiral-shaped coil and a plurality of sections. In one embodiment, an RF coil of a magnetic resonance imaging (MRI) system has a plurality of ring-shaped end-rings arranged vertically and a plurality of rods. Each of the rods are connected to the plurality of end-rings. Adjacent end-rings of the plurality of end-rings forms respective coil sections and each of the coil sections has switching blocks located between adjacent rods of the plurality of rods. The switching blocks are operable to control the continuity status of the plurality of rods in the respective coil section.

The present application claims priority to Korean Patent Application No. 10-2008-0072186 entitled “RADIO FREQUENCY COIL FOR MAGNETIC RESONANCE IMAGING APPARATUS” filed on Jul. 24, 2008, the entire content of which is incorporated herein by reference.

### BACKGROUND

1.Field

The present disclosure generally relates to a magnetic resonance imaging (MRI) system. More particularly, the present disclosure relates to a radio frequency (RF) coil of a high magnetic field MRI system.

2. Background

Magnetic resonance imaging (MRI) systems can be used in the field of medical diagnosis due to its capability of providing 3-dimensional and/or high-resolution images without harming a human body. In order to overcome deficiencies in low magnetic field MRI systems, high magnetic field MRI systems have been developed. In particular, a 7 Tesla MRI system is attracting attention in the field since it can provide images with higher signal to noise ratio (SNR) and higher resolution compared to a low magnetic field (e.g., 1.5 Tesla or 3 Tesla) MRI system. Further, a high magnetic field (7 Tesla) MRI system can provide images of cerebral cortex, thereby making it possible to provide better medical services to patients with brain diseases.

In some MRI systems, a coil for both transmission and reception (Tx/Rx birdcage coil) is used to obtain images of a human brain. In general, the coil may be shaped as a birdcage in which a plurality of rods are coupled between an upper and lower ring-shaped end-ring. The signal to noise ratio (SNR) and B1 field homogeneity characteristics of the birdcage coil are superior to volume coils having other shapes. Further, since the birdcage coil is based on a transmission line manufactured using a lumped element component model, it is easy to tune the resonator to a center frequency of the system.

However, if the existing Tx/Rx birdcage coil is used in a high magnetic field (7 Tesla) MRI system, an inhomogeneous magnetic field may be formed when imaging the axial plane (x-y plane). This occurs because the resonance frequency is proportional to the magnitude of the magnetic field resulting in short wavelengths for signals in the high magnetic field MRI system. Particularly, if the wavelength to be used is shorter than the diameter of the coil, an inhomogeneous magnetic field is formed. This may cause attenuation of the wave actually transmitted to the object. In a low magnetic field MRI system, the magnetic field generated by an RF coil can be formed homogeneously in a human brain. On the other hand, when using the existing RF coil in a high magnetic field MRI system, a homogeneous magnetic field cannot be formed in the human brain because of the distortion caused by the permittivity and the conductivity of the human body.

Specifically, in a high magnetic field MRI system, standing waves are formed inside the human brain, which is generally positioned within the RF coil. In this case, the B1 fields generated by the coil are concentrated in the middle of the brain by constructive interference. On the other hand, the B1 fields are weakened outside of the brain by destructive interference. As a result, the center image of the brain looks bright and the outside image looks dark, which makes it difficult to make a diagnosis. This problem is unavoidable in existing MRI systems for imaging a human body.

Further, when imaging an object on a y-z plane (Sagittal Plane) or x-z plane (Coronal Plane), the B1 field distribution may not be homogeneous along the z-direction due to the geometric shape of the RF coil and because the field along the z-direction cannot be homogeneously formed. The B1 field at a first distance away from the z-axis is weaker than a B1 field at a second distance closer to the z-axis, which causes an inhomogeneous magnetic field formation.

In order to address and resolve the above-mentioned problems, an RF coil that can generate a homogeneous magnetic field in a high magnetic field MRI system is required. Further, since it is difficult to generate regular magnetic field along the z-direction, an RF coil which can selectively form a magnetic field in the particular region of interest is required.

### SUMMARY OF THE INVENTION

The present disclosure provides an RF coil that in some embodiments can generate a homogeneous magnetic field in a high magnetic field MRI system. In one embodiment, an RF coil has a plurality of adjacent ring-shaped end-rings, each of the adjacent ring-shaped end-rings forming a coil section having a switching block that controls a continuity status of the coil section and a plurality of adjacent rods connecting adjacent end-rings. The switching block is located between adjacent rods.

This Summary is provided to introduce a selection of concepts in a simplified form that are further described below in the Detailed Description. The Summary is not intended to identify key features or essential features of the claimed subject matter, nor is it intended to be used to limit the scope of the claimed subject matter.

### BRIEF DESCRIPTION OF THE DRAWINGS

Arrangements and embodiments will be described in detail with reference to the following drawings in which like reference numerals refer to like elements and wherein:

FIG. 1 shows an illustrative schematic view of a spiral RF coil;

FIG. 2 shows an illustrative 2 dimensional development view of a spiral RF coil;

FIG. 3 shows an illustrative embodiment of an equivalent circuit of a spiral RF coil;

FIG. 4 shows an illustrative embodiment of a spiral coil for operation in a quadrature mode;

FIG. 5 shows an illustrative embodiment of an equivalent circuit of a birdcage-type coil which can form a magnetic field selectively along the z-direction;

FIG. 6 shows an illustrative embodiment of an equivalent circuit of a pin diode switching circuit for selectively forming a magnetic field; and

FIG. 7 shows an illustrative embodiment of an equivalent circuit of a spiral RF coil which can form a magnetic field selectively along the z-direction.

### DETAILED DESCRIPTION

A detailed description will be provided with reference to the accompanying drawings. It will be readily understood that the components of the present disclosure, as generally described and illustrated in the Figures herein, could be arranged and designed in a wide variety of different configurations. Thus, the following detailed description of the embodiments in accordance with the present disclosure, as represented in the Figures, is not intended to limit the scope of the disclosure, as claimed, but is merely representative of certain examples of embodiments in accordance with the disclosure. The presently described embodiments will be best understood by reference to the drawings, wherein like parts are designated by like numerals throughout.

Spiral Coil for Forming Homogeneous Magnetic Field

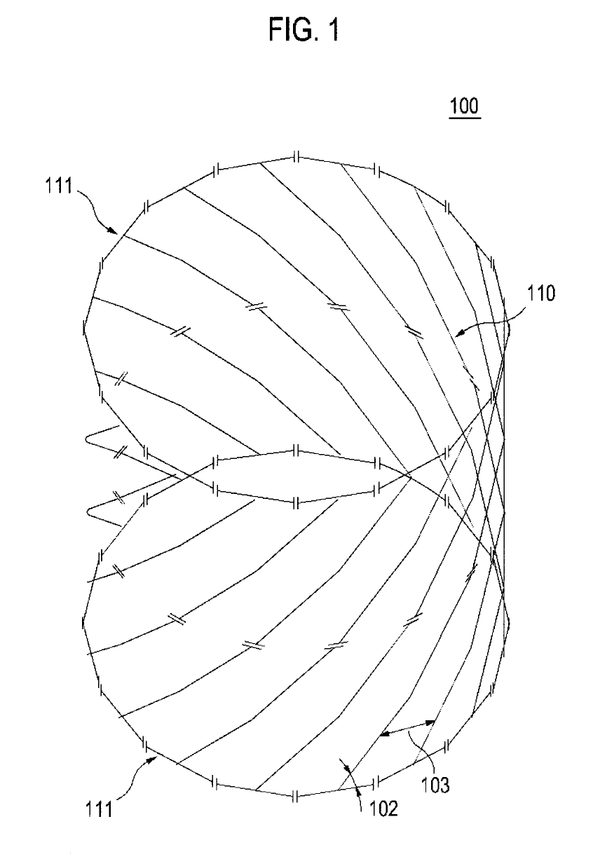

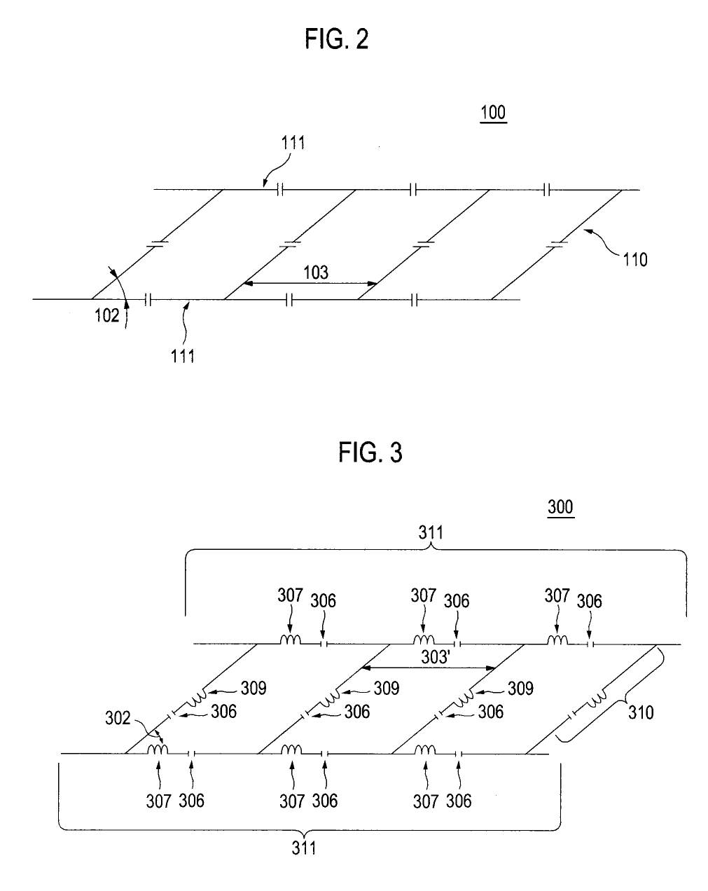

FIG. 1 shows an illustrative schematic view of a spiral RF coil and FIG. 2 shows an illustrative 2 dimensional development view of a spiral RF coil 100. The spiral RF coil 100 in this embodiment has ring-shaped upper and lower end-rings 111, and a plurality of rods 110 connected to the upper and lower end-rings 111. As shown in FIG. 1, the spiral RF coil 100 may have a multiple-spiral shape, with the rods 110 connecting to the end-rings 111 diagonally at a spiral angle 102. The rods 110 are aligned apart from the adjacent rods 110 at a predetermined distance. The distance between the adjacent rods 110 are defined as a window angle 103. The end-rings 111 may function as the passages of electrical current. The magnetic field may be substantially created by the plurality of rods 110.

Although the rods 110 and the end-rings 111 are shown as solid lines in FIGS. 1 and 2, in the actual implementation of the spiral RF coil, the rods 110 and the end-rings 111 may have a certain width. As the width of the rod 110 gets wider, or as the number of the rods 110 increases, the window angles 103 become narrower. As the window angles 103 get narrower, the mutual inductance between the adjacent rods 110 increases. Thus, the number of rods should be limited. In one embodiment of an MRI system for imaging a human brain, the use of an RF coil having 16 rods may be desirable to form a homogeneous magnetic field.

FIG. 3 shows an illustrative embodiment of an equivalent circuit of a spiral RF coil. The equivalent circuit of the spiral RF coil 300 is a band-pass filter.

The equivalent circuit of the spiral RF coil 300 in this embodiment has upper and lower end-rings 311, and a plurality of rods 310 connected to the upper and lower end-rings 311. Although the circuit in FIG. 3 shows three meshes having four rods 310 and two end-rings 311, the present disclosure is not limited to such embodiment.

Each section of the end-ring 311 between rods 310 may be modeled as a capacitor 306 and inductance element 307 of the coil. Each of the rods 310 has a capacitor 306 and a mutual inductance element 309 reflecting a mutual inductance created by the inductance elements 307. These capacitors may serve to conform the resonance frequency with the frequency of MRI system.

The rods 310 may be arranged apart from each other at the distance of window angle 303. Further, the rods 310 may be connected to the end-rings 311 diagonally at the spiral angle 302. Due to the spiral angle 302, the mutual inductances of the spiral RF coil may become different from that of the existing birdcage coil. Thus, the magnetic field may be controlled by varying the spiral angle 302.

The propagation constant of the field is closely related to the wavelength. If the wavelength gets longer, the propagation constant becomes smaller. Since the propagation constant generally increases in the human brain, the phase shift of the field increases accordingly. This may result in an inhomogeneous magnetic field. According to an embodiment of the spiral coil 100 of the present disclosure, however, the wavelength along the axial plane may be increased by tilting the rods 310 by the spiral angle 302. As a result, the propagation constant along the axial plane may decrease. Therefore, a homogeneous magnetic field may be formed in the human brain so that an improved image may be obtained. The spiral angle 302 may in some embodiments be 45 degrees.

The spiral RF coil 300 may be operable in either a linear mode or a quadrature mode. Operating in the quadrature mode may produce an improved SNR compared to when operating in the linear mode. Thus, the following embodiments will be described assuming that the spiral RF coil operates in the quadrature mode. For operation in the quadrature mode, the coil may be designed so that the number of the rods 310 is in multiples of four.

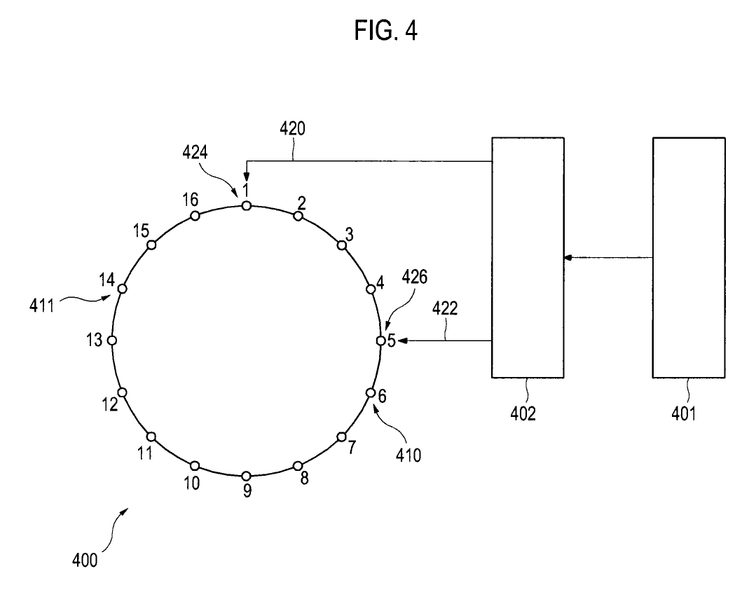

FIG. 4 shows an illustrative embodiment of a spiral coil for operation in the quadrature mode. In the quadrature mode, the signal from a radio frequency amplifier 401 and a quadrature hybrid coupler 402 may be inputted to a spiral RF coil 400. The spiral RF coil 400 may have ring-shaped upper and lower end-rings 411, and a plurality of rods 410 connected to the upper and lower end-rings 411 at regular intervals with a predetermined spiral angle. In the embodiment shown in FIG. 4, the spiral RF coil 400 has 16 rods 410.

The radio frequency amplifier 401 may provide RF signals to the quadrature hybrid coupler 402. The quadrature hybrid coupler 402 may divide the RF signal from the radio frequency amplifier 401 into two signals 420 and 422 which differ in phase from each other by 90-degrees, and provide them to the input terminals of the coil 400. Since the coil for imaging a human brain generally has a round shape and the electrical current through the rod is a sinusoidal wave, the signals divided by the coupler 402 may be applied to the input terminals which are located 90 degrees apart. As shown in FIG. 4, for example, the signals may be applied respectively to a first input terminal 424 and a fifth input terminal 426, which are located 90 degrees apart. When applying the quadrature driving current, the magnetic field may be formed around the z-axis with a phase difference of 90 degrees maintained between the rods 410.

Configuration of Coil for Selectively Forming Magnetic Field

According to an embodiment of the present disclosure, a selective image may be obtained using the RF coil of an MRI system.

Due to the structural incompleteness of the coil of an MRI system, a homogeneous field may not be formed and a certain field distribution may occur on the y-z plane (Sagittal Plane) and the x-z plane (Coronal Plane). Specifically, it is difficult to obtain an image, which is uniform along the z-direction of the coil, since the high frequency field has a short wavelength. According to the present embodiment, the entire image along the z-direction of a coil may be obtained first, and for the region of interest, the higher resolution image may be obtained.

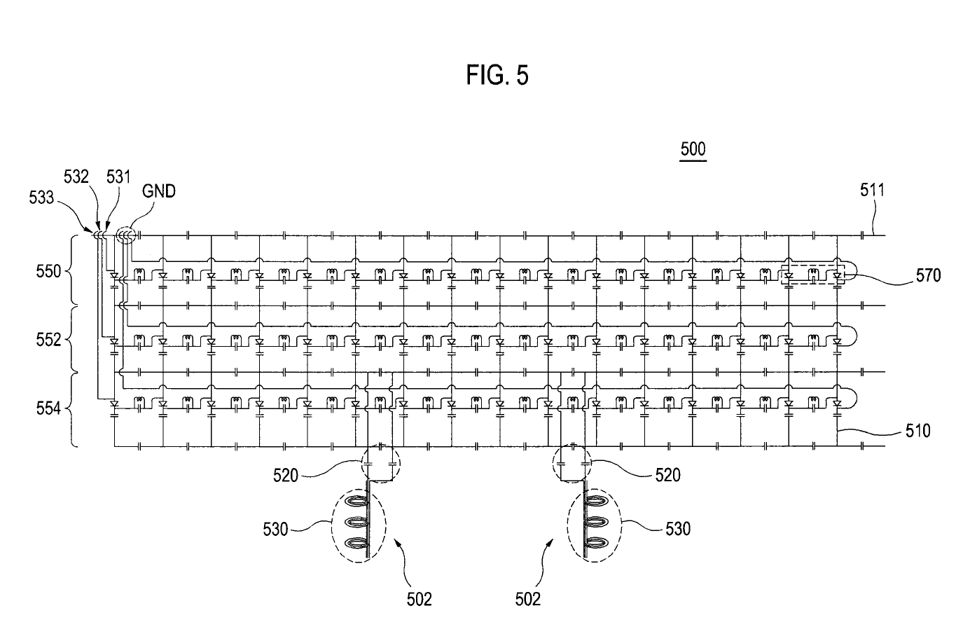

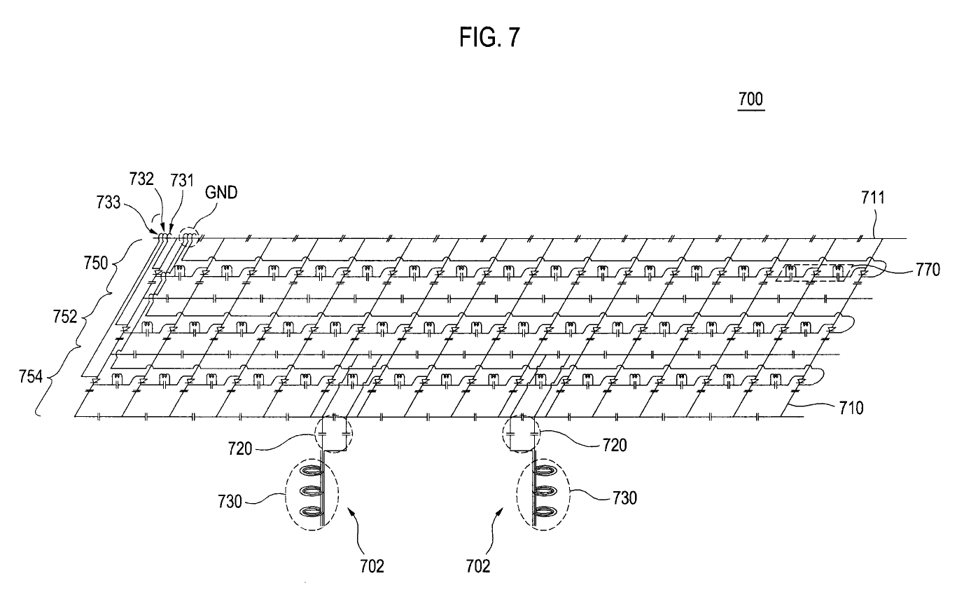

FIG. 5 shows an illustrative embodiment of an equivalent circuit of a birdcage-type coil that can form magnetic field selectively along the z-direction. The equivalent circuit 500 may be implemented as a spiral coil mentioned above. The equivalent circuit of the spiral coil in accordance with the present embodiment will be described in connection with FIG. 7.

As shown in FIG. 5, the equivalent circuit 500 of the coil in accordance with the present embodiment has a plurality of rods 510 and a plurality of end-rings 511, forming a plurality of sections 550, 552 and 554, creating a structure wherein a plurality of the existing birdcage RF coils are arranged vertically. Each of the sections 550, 552 and 554 correspond to each part of an object, which is divided along the z-direction. Although the circuit 500 in FIG. 5 has three sections, the present disclosure is not limited to such embodiment.

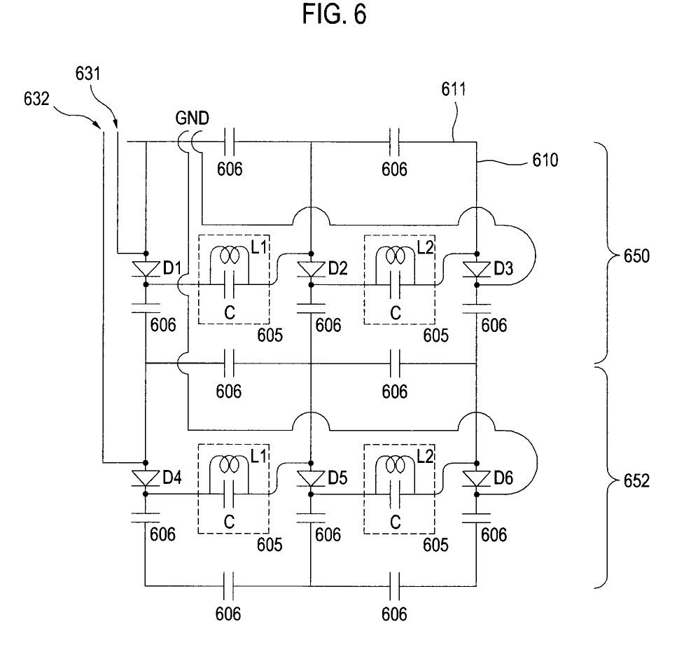

Separate input biases 531, 532 and 533 are applied to the respective sections of the circuit. The input biases 531, 532 and 533 may be inputs for turning on/off PIN diodes, which will be described later. In the embodiment shown in FIG. 5, the input bias 531 is applied to the input terminal of a first section of the coil 550, the input bias 532 is applied to the input terminal of a second section of the coil 552, and the input bias 533 is applied to the input terminal of a third section of the coil 554. Further, each section of the coil may be coupled to the ground GND. Each section of the coil may have a PIN diode switching circuits 570 for selectively forming a magnetic field. The PIN diode switching circuit 570 may be a switching block located between the adjacent rods. The PIN diode switching circuit 570 may comprise coupling lines and PIN diodes. The PIN diode switching circuit 570 may be operable to control the continuity status according to the input bias. Details of the PIN diode switching circuit 570 will be described in connection with FIG. 6.

The RF coil 500 may further have RF signal input terminals 502 to receive the signals for stimulating the protons of the object by providing energy to the object. In the embodiment shown in FIG. 5, the RF coil 500 may have two RF signal input terminals 502 for operation in quadrature mode.

The operations of inputting the RF signal to the RF coil 500 are as follows. As described in connection with FIG. 4, in the quadrature mode, the RF signal from the radio frequency amplifier (not shown) may be divided by the quadrature hybrid coupler (not shown) into two RF signals which differ in phase from each other by 90-degrees, and these RF signals may be inputted to the input terminals 502 respectively.

In one embodiment, for effective transferring of the RF signals from the quadrature hybrid coupler (not shown), each of the input terminals of the coil may have an impedance matching circuit 520. If the impedance matching circuit 520 is not included in the circuit, the RF signals may not be efficiently provided to the coil and the protons of the object surrounded by the coil may not be effectively stimulated.

In one embodiment, coaxial cables may be used to connect the impedance matching circuit 520 with the quadrature hybrid coupler. When long coaxial cables are used, outer noise may occur. In order to remove the outer noise, a shield current suppression cable trap 530 may be used.

FIG. 6 shows an illustrative embodiment of an equivalent circuit of a pin diode switching circuit for selectively forming a magnetic field. The circuit shown in FIG. 6 has three rods 610 and three end-rings 611, forming a first section of coil 650 and a second section of coil 652. Similar to FIG. 5, an input bias 631 is applied to the input terminal of the first section of coil and an input bias 632 is applied to the input terminal of the second section of coil, respectively. The first section of coil and the second section of coil are coupled to the ground GND.

As discussed above, each of the rods 610 has a capacitor 606. Further, each of the end-rings 611 has a capacitor 606. The rods 610 in each section have PIN diodes D1-D6. Each output terminal of the PIN diodes is connected to the capacitor 606. The input biases 631 and 632 are applied to the respective input terminals of the first diodes D1 and D4 in the respective sections 650 and 652. The output terminals of the first diodes D1 and D4 are connected to the input terminals of the second diodes D2 and D5 of the adjacent rod 610 respectively. Likewise, the output terminals of the first diodes D2 and D5 may be connected to the input terminals of the third diodes D3 and D6 of the adjacent rod 610 respectively. The output terminals of the third diodes D3 and D6 are connected to the ground GND.

In the present embodiment, some magnetic fields may be induced by the coupling lines connecting the output terminal of a certain diode with the input terminal of the diode of the adjacent rod. Since the magnetic field from the coupling lines may distort the magnetic field to be provided to the object by the RF coil, in order to remove the magnetic field from the coupling lines, a band-reject filter 605 may be included to each of the coupling lines. In the embodiment shown in FIG. 6, the band-reject filter 605 has an inductor L and a capacitor C coupled in parallel. Other types of band-reject filters may be used.

The PIN diodes D1-D6 may be used for switching operations in the high-frequency circuit. The PIN diodes D1-D6 are adapted to allow an electric current to pass in one direction. The electrical properties of the PIN diodes D1-D6 are the same as those of a resistor. That is, the electric current passing through the PIN diode may be determined according to the voltage applied to the PIN diode. However, the electric current passing through the PIN diode is not proportional to the voltage applied thereto, but has a functional relationship with the voltage. The operations of the circuit shown in FIG. 6 are as follows. The input biases 631 and 632 are applied to the input terminals of the first diodes D1 and D4 of sections 650 and 652 respectively. For the first section 650, the first input bias 631 are applied to the input terminal of the diode D1. If the applied voltage is higher than the threshold voltage of the diode D1 (e.g., 0.7V), the diode D1 may function as a short circuit. Likewise, if the voltages applied to the diodes D2 and D3 are higher than the threshold voltage of the diodes D2 and D3, the diodes D2 and D3 may function as short circuits. When the electric current applied by the bias is sufficiently higher than the electric current exhausted by the diodes in the first section, then all the diodes in the first section may function as short circuits. When the applied electric current is not high enough, the diodes may function as open circuits and the electric current cannot flow in the circuit of the corresponding section.

For the second section 652, the second input bias 632 may be applied to the input terminal of the diode D4 similarly to the operations for the first section 650. If the applied voltage is higher than the threshold voltage of the diode D4 (e.g., 0.7V), the diode D4 may function as a short circuit. Likewise, if the voltages applied to the diodes D5 and D6 are higher than the threshold voltage of the diodes D5 and D6, the diodes D5 and D6 may function as short circuits. When the electric current applied by the bias is sufficiently higher than the electric current exhausted by the diodes in the second section, then all the diodes in the second section may function as short circuits. When the applied electric current is not high enough, the diodes may function as open circuits and the electric current cannot flow in the circuit of the corresponding section. In this way, the electric current in the circuit of each section can be controlled by adjusting the input biases 631 and 632.

Using the configuration described above, ON/OFF status of each section of the coil can be controlled by applying DC bias to each section of the coil or not. In this way, the image of the portion of object corresponding to a certain section of the coil can be obtained in a selective manner. For example, when it is required to obtain an image of the lower section of an object such as a human brain (i.e., the second section 652), it may be possible to obtain the lower half of the image of the object by providing a DC voltage to the second input 632 and not providing DC voltage to the first input 631. As the number of sections increase, minutely subdivided images along the z-direction can be obtained.

Although FIGS. 5 and 6 show the embodiments having switching circuits that may control the continuity status of the rods with PIN diodes and DC biases, the present disclosure is not limited in such embodiments. Any configurations of switching circuits may be implemented to control the continuity status of the rods. For example, electrical switching devices may be used to control the continuity status of the rods by the electrical signal.

FIG. 7 shows an illustrative embodiment of an equivalent circuit of a spiral RF coil which can form magnetic field selectively along the z-direction. The circuit 700 has a plurality of rods 710 and a plurality of end-rings 711, forming a plurality of sections 750, 752 and 754, which create a structure wherein a plurality of the spiral RF coils are arranged vertically. Similar to the circuit 500 shown in FIG. 5, the circuit 700 has input biases 731, 732 and 733 a PIN diode switching circuits 770. The circuit 700 may further have RF signal input terminals 702.

In one embodiment, each of the input terminals 702 may have an impedance matching circuit 720. In another embodiment, when long coaxial cables are used to connect the impedance matching circuit 720 with the quadrature hybrid coupler, the circuit 700 may further have a shield current suppression cable trap 730.

Except that the RF coils of the present embodiment is a spiral RF coil, the configurations and operations of the circuit 700 are the same as those of circuit 500 shown in FIG. 5. Applying the spiral RF coils shown in FIG. 7, homogeneous magnetic fields may be obtained resulting in a higher signal to noise ratio. This can also result in improved images as well as the ability to create selective images along the z-direction.

The foregoing merely describes some embodiments of the present invention. From the above descriptions, accompanying drawings and claims, those skilled in the art can readily recognize that various modifications can be made without departing from the spirit and scope of the appended claims. The above descriptions are thus to be regarded as illustrative rather than limiting.

What is claimed is:

1. An RF coil comprising:
a plurality of adjacent ring-shaped end-rings, each of the adjacent ring-shaped end-rings forming a coil section comprising a switching block that controls a continuity status of the coil section; and
a plurality of adjacent rods connecting adjacent end-rings of the plurality of end-rings, the switching block located between adjacent rods.

2. The RF coil of claim 1, wherein each of the plurality of adjacent rods connects the adjacent ring-shaped end-rings diagonally at a predetermined spiral angle.

3. The RF coil of claim 2, wherein the spiral angle is 45 degrees.

4. The RF coil of claim 1, wherein the switching block comprises a coupling line that connects the adjacent rods to one another, the coupling line comprising a band-reject filter.

5. The RF coil of claim 1, wherein the RF coil operates in a quadrature mode and wherein the number of the rods is 16.

6. The RF coil of claim 5, further comprising two RF signal input terminals, the RF signal input terminal comprising an impedance matching circuit and a shield current suppression cable trap.

7. An MRI system comprising an RF coil, said RF coil comprising:
a plurality of adjacent ring-shaped end-rings, each of the adjacent ring-shaped end-rings forming a coil section comprising a switching block that controls a continuity status of the coil section; and
a plurality of adjacent rods connecting adjacent end-rings of the plurality of end-rings, the switching block located between adjacent rods.
